(19) United States
(12) Patent Application Publication
(10) Pub. No.: US 2009/0108319 A1
(43) Pub. Date: Apr. 30, 2009

(54) DRAM STACK CAPACITOR AND FABRICATION METHOD THEREOF

(75) Inventors: Teng-Wang Huang, Taoyuan County (TW); Chang-Rong Wu, Taoyuan County (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 12/017,164

(22) Filed: Jan. 21, 2008

(30) Foreign Application Priority Data
Oct. 31, 2007 (TW) TW96140942

(51) Int. Cl. H01L 29/94; H01L 21/8242

(52) U.S. Cl. 257/309; 438/255; 257/E29.345; 257/E21.646

(57) ABSTRACT

A DRAM stack capacitor and a fabrication method thereof has a first capacitor electrode formed of a conductive carbon layer overlying a semiconductor substrate, a capacitor dielectric layer and a second capacitor electrode. The first capacitor electrode is of crown shape geometry and possesses an inner surface and an outer surface. The DRAM stack capacitor features the outer surface of the first capacitor electrode as an uneven surface.

### BACKGROUND OF THE INVENTION

1. Field of the Invention

The present invention relates to a semiconductor and a fabrication method thereof, and in particularly relates to a dynamic random access memory (DRAM) stack capacitor and a fabrication method thereof.

2. Description of the Related Art

Conventionally, various methods for increasing the capacitance of the dynamic random access memory stack capacitor have been proposed.

For example, in U.S. Pub. No. 2007/0001208, a dynamic random access memory stack capacitor and a fabrication method thereof are disclosed. In the fabrication method, a sacrificial dielectric layer is used to form a crown-shaped capacitor electrode made of conductive carbon. Because the capacitor electrode possesses inner and outer surfaces, the effective area of the capacitor electrode is larger so that capacitance increases. As shown in FIG. 1, the dynamic random access memory stack capacitor includes a semiconductor substrate 1, an etching stop layer 3, a lower capacitor electrode 6, a capacitor dielectric layer 9, and an upper capacitor electrode 8. The etching stop layer 3 includes a conductive region 2 for electrically connecting the stack capacitor to the semiconductor substrate 1.

A novel dynamic random access memory stack capacitor and a fabrication method thereof, which further raises the effective area of the capacitor electrode for increasing capacitance, is thus desirable.

### BRIEF SUMMARY OF THE INVENTION

In one embodiment of the invention, a fabrication method for a dynamic random access memory stack capacitor is disclosed. The fabrication method comprises the steps of: disposing a plurality of semi-spherical grains on sidewalls of an opening in a sacrificial layer over a substrate; filling the opening with a first conductive material; removing the sacrificial layer and the semi-spherical grains to form a first electrode, wherein a plurality of arc-shape cavities are formed on an outer surface of the first electrode; forming a dielectric layer on the first electrode; and forming a second conductive material over the first electrode to form a second electrode.

In another embodiment of the invention, a structure of a dynamic random access memory stack capacitor is also disclosed. The structure comprises a substrate, a conductive layer on the substrate, a lower electrode on the conductive layer, an upper electrode on the lower electrode, and an insulting layer interposed between the upper and lower electrodes. Specifically, the structure features the formation of a plurality of arc-shaped cavities on an outer surface of the first electrode.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is cross section of a fabrication method for a conventional DRAM stack capacitor; and

FIG. 2˜9 are cross sections of an embodiment of a method for fabricating a DRAM stack capacitor according to the invention.

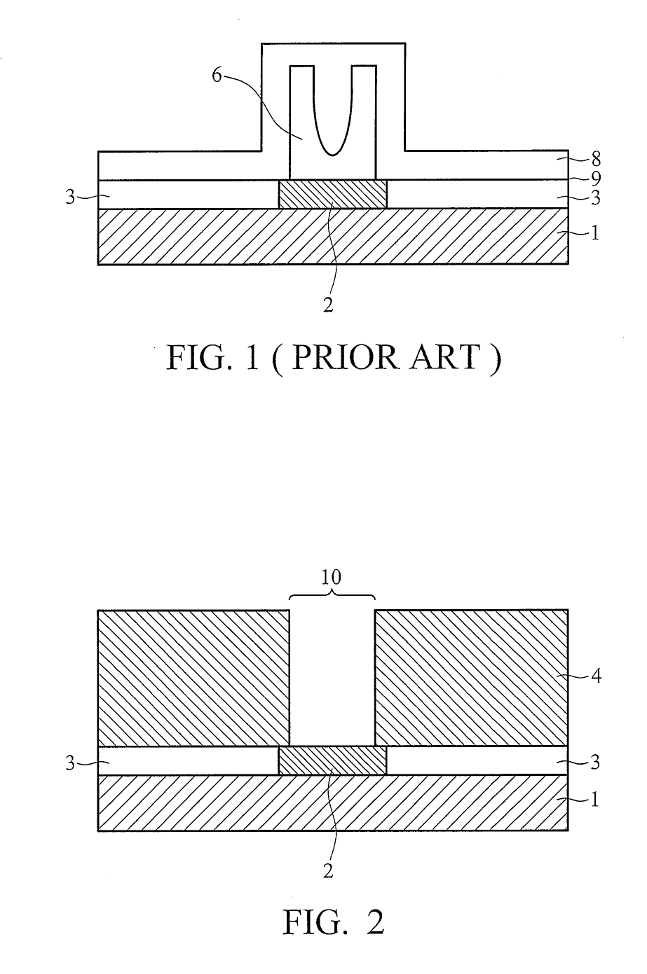

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

One embodiment discloses a fabrication method for a dynamic random access memory stack capacitor according to the invention.

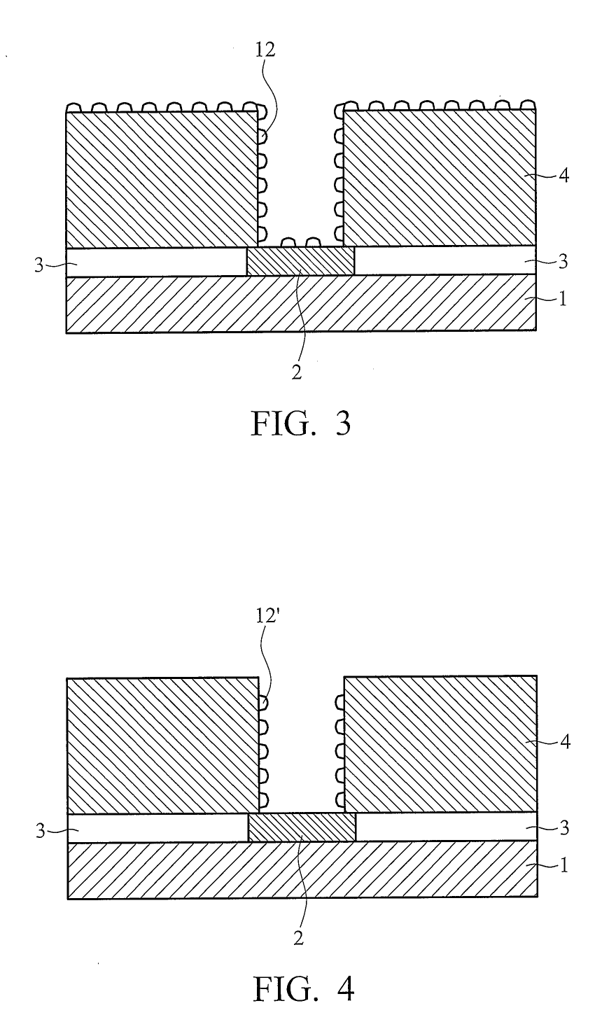

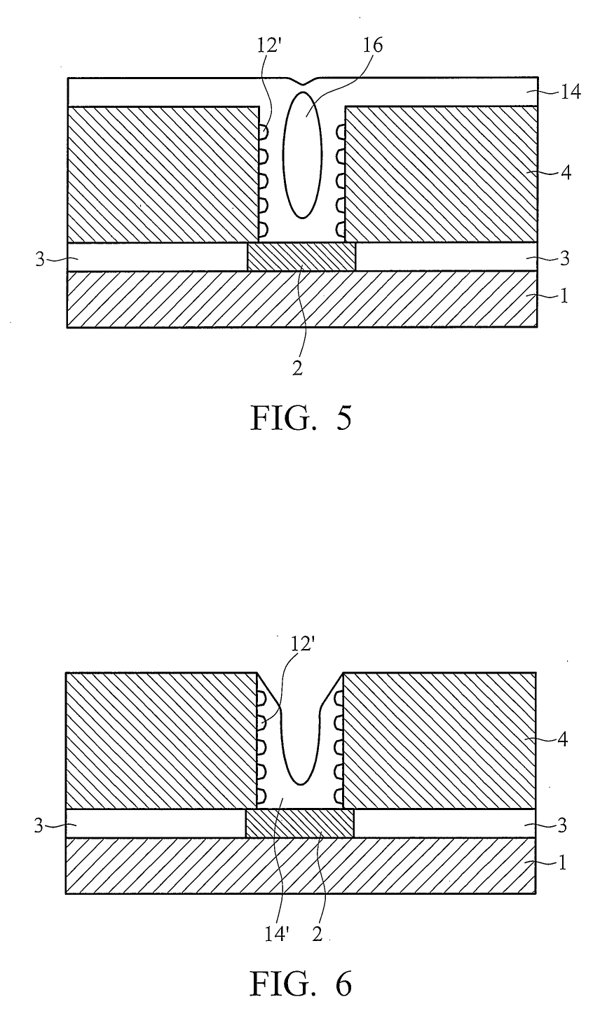

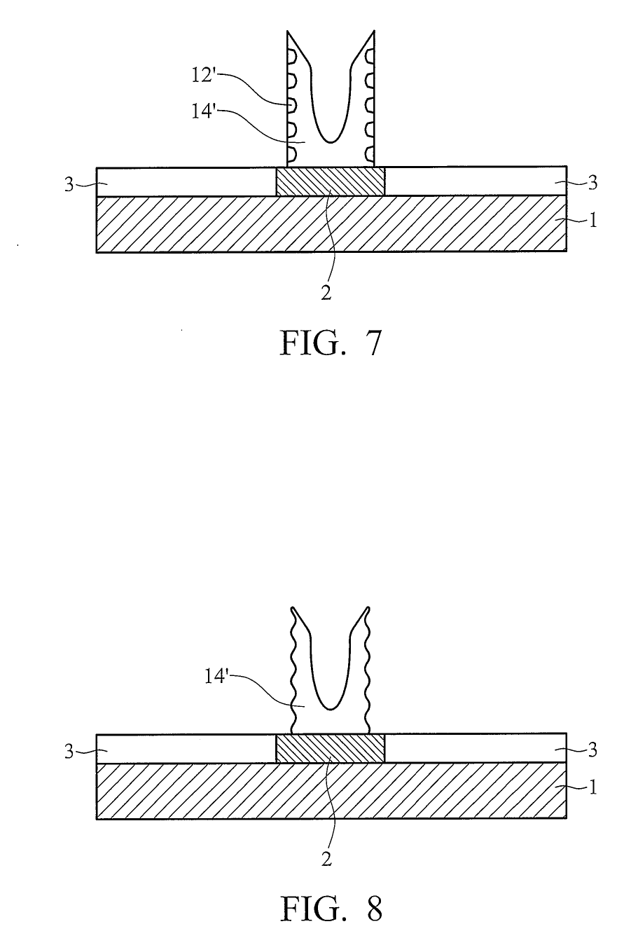

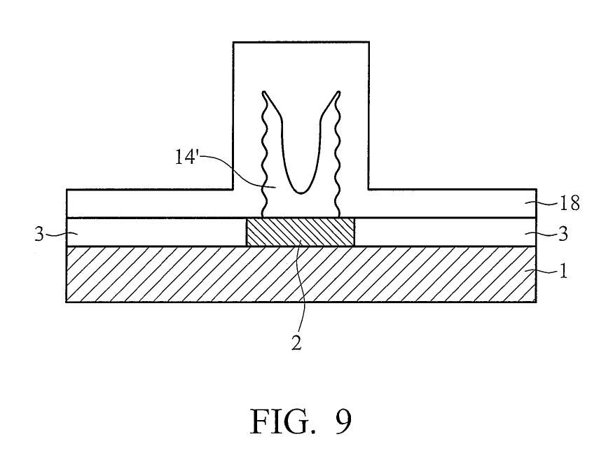

As shown in FIG. 2, an etching stop layer 3 and a sacrificial dielectric layer 4 having an opening 10 is formed on a semiconductor substrate 1 in sequence. Typically, the semiconductor substrate 1 is made up of a silicon wafer including metal layers (not shown), interlayer dielectric layers (not shown) and other elements (for example, a metal oxide semiconductor field effect transistor). The etching stop layer 3 uses materials such as silicon nitride. The sacrificial dielectric layer 4 uses materials such as silicon dioxide. The formation of the etching stop layer 3 includes typical deposition processes. The sacrificial dielectric layer 4 having an opening 10 is formed, for example, by typical photolithography processes. The etching stop layer 3 has a conductive region 2 which is exposed via the opening 10, and the conductive region 2 is typically made up of TiSiₓ, CoSiₓ, NiSiₓ, or doped semiconductor materials.

As shown in FIG. 3, a layer 12 of semi-spherical grains is then formed covering the sacrificial dielectric layer 4 and the sidewalls and bottom of the opening 10. The layer 12 of semi-spherical grains uses materials such as silicon, and the formation thereof includes a typical epitaxy processes.

As shown in FIG. 4, a typical photolithograph process or an etching process is performed on the layer 12 of semi-spherical grains to leave a pattern 12′ of semi-spherical grains on the sidewalls of the opening 10. For example, a photoresist material (not shown) is used to fill the opening 10 and to cover the surface of the sacrificial. dielectric layer 4. Thereafter, the photoresist material is patterned, and the photoresist material outside the opening 10 is then removed. Next, the layer 12 of semi-spherical grains is partly removed except for the part remaining on the sidewalls of the opening 10 i.e. the pattern 12′ of semi-spherical grains. Each semi-spherical grain of the pattern 12′ has a diameter between 5 and 50 nm.

As shown in FIG. 5, a conductive material 14 is utilized to fill the opening 10 and to cover the surface of the sacrificial dielectric layer 4. The conductive material 14, for example, is conductive carbon. Due to the deposition process of the conductive material 14, a void 16 is thus formed within the opening 10.

A recess etching process is performed to open the void 16 within the opening 10 and to remove the conductive material from the surface of the sacrificial dielectric layer 4, thus, the residual conductive material covering the pattern 12′ of semi-spherical grains and the bottom of the opening 10 serves as a first capacitor electrode 14′ (i.e. the lower electrode). The recess etching process is performed using oxygen or argon plasma, for example.

As shown in FIG. 7, the sacrificial dielectric layer 4 is removed to expose the surface (i.e. the outer surface) of the first capacitor electrode 14′ possessing the pattern 12′ of semi-spherical grains and a portion of the surface of the etching stop layer 3. The removal of the sacrificial dielectric layer 4 includes an etching process.

As shown in FIG. 8, the pattern 12′ of semi-spherical grains on the outer surface of the first capacitor electrode 14′ is then removed, thus, leaving a wavy surface on the outer surface of the first capacitor electrode 14′. That is, arc-shaped cavities are formed on the outer surface of the first capacitor electrode 14′. The formation increases the effective area of the outer surface of the first capacitor electrode 14′, thus, leading to increased capacitance.

As shown in FIG. 9, a capacitor dielectric layer and a second capacitor electrode 18 (i.e. the upper capacitor) are formed on the exposed surfaces of the first capacitor electrode 14′ and the etching stop layer 3 in sequence. The first capacitor electrode 14′, the capacitor dielectric layer and the second capacitor electrode 18 constitute a capacitor. The capacitor dielectric layer can be high dielectric constant materials, such as Al₂O₃, Ta₂O₅, TiO₂ or ferroelectrics, and the formation thereof can be by chemical vapor deposition. The second capacitor electrode 18 can use materials such as metal or conductive carbon, and the metal materials can be Pt, Ir, Ru, or Pd. The formation of the second capacitor electrode 18 includes chemical vapor deposition, physical vapor deposition or reactive ion sputtering. In other embodiments, the second capacitor electrode 18 can use metal oxide such as IrO₂ or RuO₂.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A fabrication method for a dynamic random access memory stack capacitor, comprising:
disposing a plurality of semi-spherical grains on sidewalls of an opening in a sacrificial layer over a substrate;
filling the opening with a first conductive material;
removing the sacrificial layer and the semi-spherical grains to form a first electrode, wherein a plurality of arc-shaped cavities are formed on an outer surface of the first electrode;
forming a dielectric layer on the first electrode; and
forming a second conductive material over the first electrode to form a second electrode.

2. The fabrication method as claimed in claim 1, wherein the step of disposing the semi-spherical grains on the sidewalls of the opening comprises:
forming a layer of semi-spherical grains which lines the opening and covers the sacrificial layer; and
performing photolithography and etching processes to leave a pattern of semi-spherical grains on the sidewalls of the opening.

3. The fabrication method as claimed in claim 2, wherein the step of forming the first electrode over the pattern of semi-spherical grains and a bottom portion of the opening comprises:
forming the first conductive material which lines the opening and covers the sacrificial layer; and
performing a recess etching process to remove the first conductive material from the sacrificial layer until only a portion of the first conductive material remains in the opening, wherein the remaining portion serves as the first electrode.

4. The fabrication method as claimed in claim 3, wherein the removal of the pattern of semi-spherical grains comprises an isotropic wet etching process.

5. The fabrication method as claimed in claim 1, wherein the first conductive material is a conductive carbon layer.

6. The fabrication method as claimed in claim 1, wherein the second conductive material is a metal layer.

7. The fabrication method as claimed in claim 3, wherein the photolithography and etching processes use an anisotropic etching process.

8. The fabrication method as claimed in claim 4, wherein:
the first conductive material is a conductive carbon layer;
the second conductive material is a metal layer; and
each semi-spherical grain has a diameter between 5 and 50 nm.

9. A structure of a dynamic random access memory stack capacitor, comprising:
a substrate;
a conductive layer on the substrate;
a lower electrode on the conductive layer, wherein a plurality of arc-shaped cavities are formed on an outer surface of the first electrode; and
an upper electrode on the lower electrode, wherein an insulting layer is interposed therebetween.

10. The structure as claimed in claim 9, wherein the lower electrode is a conductive carbon layer.

11. The structure as claimed in claim 10, wherein the upper electrode is a conductive carbon layer or a metal layer.

12. The structure as claimed in claim 9, wherein:
the first conductive material is a conductive carbon layer;
the second conductive material is a conductive carbon layer or a metal layer; and
each semi-spherical grain has a diameter between 5 and 50 nm.
